(19) United States
(12) Patent Application Publication
(10) Pub. No.: US 2025/0366309 A1
(43) Pub. Date: Nov. 27, 2025

(54) ORGANIC LIGHT EMITTING ELEMENT AND MANUFACTURING METHOD THEREOF

(71) Applicant: CANON KABUSHIKI KAISHA, Tokyo (JP)

(72) Inventors: OSAMU AKUTSU, Kanagawa (JP); JUN YAMAGUCHI, Kanagawa (JP)

(21) Appl. No.: 19/197,787

(22) Filed: May 2, 2025

(30) Foreign Application Priority Data
May 24, 2024 (JP) 2024-084717

(51) Int. Cl. H10K 50/84; H10K 71/16

(52) U.S. Cl. CPC H10K 50/84; H10K 71/166

(57) ABSTRACT

An organic light emitting element including a light emitting region on a part of a substrate, the light emitting region including at least one electrode, an organic compound layer that covers the at least one electrode, and a metallic layer that covers the organic compound layer, with a discrimination part including at least one of a convex part and a concave part arranged on at least one of an outer edge of the organic compound layer and an outer edge of the metallic layer.

BACKGROUND

### Field

The present disclosure relates to an organic light emitting element, a manufacturing method for the organic light emitting element, and apparatuses and devices using the organic light emitting element.

### Related Art

As a light emitting device for emitting high-luminance light with low power, capable of being reduced in size, an organic electroluminescence element (“organic EL element” or “organic light emitting element”) is mounted on display apparatuses and illumination apparatuses. Generally, the organic EL element has a laminated structure in which a plurality of layers, such as an anode electrode, an organic compound layer, and a cathode layer are laminated on a substrate. The organic compound layer includes a hole transport layer, a light emitting layer, and an electron transport layer. A vacuum vapor deposition method for forming a film on a substrate by using vaporization and sublimation and a film formation method for forming a film by applying organic materials dissolved in a solvent through an ink jet method or a spin coat method are provided as methods for forming the laminated structure.

A vacuum vapor deposition method using a vapor deposition mask having openings according to a desired pattern has been known as a general manufacturing method for forming a plurality of layers on a substrate. In the vapor deposition method, in order to form a desired pattern on a substrate, a vapor deposition mask having openings according to the desired pattern is placed between the substrate and a vapor-deposition material source. Then, organic light emitting elements are manufactured by forming a film made of vapor-deposition materials on the substrate by executing film formation.

Normally, a chip including light emitting regions of a plurality of organic EL elements are simultaneously created on a single substrate, each of the plurality of organic EL elements is acquired by cutting the chip. At this time, there is a case where discrimination information is applied to each of the organic EL elements in order to discriminate each of the cut organic EL elements by identifying a position of the organic

EL element within the substrate.

According to a technique discussed in Japanese Patent Application Laid-Open No. 2011-171128, in order to discriminate each of organic light emitting elements, a discrimination number is printed on each of uncut organic light emitting elements by using a laser marker.

However, because of increase in size of a silicon wafer used as a substrate and reduction in size of the organic light emitting element, the number of organic light emitting elements acquired from a single substrate (i.e., the number of acquirable organic light emitting elements) is increased. Under such circumstances, the method in which a discrimination number for each of the organic light emitting elements is individually formed is problematic in terms of increased processing loads.

A method for collectively forming discrimination numbers by exposing a substrate to light through a photolithography technique may be provided for applying discrimination information. However, an exposure facility is required, and another apparatus has to be prepared in a case where the user wishes to apply more discrimination numbers than those set already. Therefore, conventional methods may be problematic at least in view of increased facility investment.

### SUMMARY

To overcome shortcomings of conventional systems, in the present disclosure, discrimination information is formed for each of organic light emitting elements in a simple manner when the organic light emitting elements are manufactured from a single substrate, so that when analysis is to be conducted after the organic light emitting elements are cut and separated from the substrate, a position of each of the organic light emitting elements within the substrate can be identified. The present disclosure allows for formation of the discrimination information without increasing manufacturing processing loads and facilities. Thus, even in a case where discrimination information is reduced in size in tandem with reduction in size of the organic light emitting element, an organic light emitting element may be obtained on which discrimination information recognizable easier than a letter or a symbol is formed.

According to an aspect of the present disclosure, an organic light emitting element is provided that includes a light emitting region on a part of a substrate, the light emitting region including at least one electrode, an organic compound layer that covers the at least one electrode, and a metallic layer that covers the organic compound layer. A discrimination part including at least one of a convex part and a concave part is arranged on at least one of an outer edge of the organic compound layer and an outer edge of the metallic layer.

Further features of the present disclosure will become apparent from the following description of exemplary embodiments with reference to the attached drawings.

### BRIEF DESCRIPTION OF THE DRAWINGS

FIGS. 1A and 1B illustrate schematic plan views of uncut chips of organic light emitting elements according to an exemplary embodiment of the present disclosure.

FIGS. 2A and 2B illustrate schematic plan views of vapor deposition masks used for manufacturing the organic light emitting elements in FIGS. 1A and 1B.

FIG. 3 illustrates a schematic cross-sectional view of a configuration of a vapor deposition apparatus.

FIG. 4 illustrates a schematic plan view of an uncut chip of conventional organic light emitting elements.

FIGS. 5A to 5C illustrate schematic plan views of uncut chips of organic light emitting elements according to another exemplary embodiment of the present disclosure.

FIGS. 6A and 6B illustrate schematic plan views of uncut chips of organic light emitting elements according to another exemplary embodiment of the present disclosure.

FIGS. 7A and 7B illustrate schematic plan views of uncut chips of organic light emitting elements according to another exemplary embodiment of the present disclosure.

FIG. 8 illustrates a schematic plan view of a basic structure of an organic light emitting element.

FIGS. 9A and 9B illustrate schematic plan views of organic light emitting elements according to Example 1 of the present disclosure.

FIG. 10 illustrates a schematic plan view of an uncut chip of organic light emitting elements according to Example 2 of the present disclosure.

FIGS. 11A to 11H illustrate schematic enlarged plan views of discrimination parts of organic light emitting elements according to Example 3 of the present disclosure.

FIG. 12A illustrates a schematic cross-sectional view of an example of a pixel included in a display apparatus according to an exemplary embodiment of the present disclosure. FIG. 12B illustrates a schematic cross-sectional view of an example of a display apparatus using organic light emitting elements according to an exemplary embodiment of the present disclosure.

FIG. 13 illustrates a schematic view of an example of a display apparatus according to an exemplary embodiment of the present disclosure.

FIG. 14A illustrates a schematic view of an example of an image capturing apparatus according to an exemplary embodiment of the present disclosure. FIG. 14B illustrates a schematic view of an example of an electronic device according to an exemplary embodiment of the present disclosure.

FIG. 15A illustrates a schematic view of an example of a display apparatus according to an exemplary embodiment of the present disclosure. FIG. 15B illustrates a schematic view of an example of a foldable display apparatus.

FIG. 16A illustrates a schematic view of an example of an illumination apparatus according to an exemplary embodiment of the present disclosure. FIG. 16B illustrates a schematic view of an example of an automobile having an automotive lamp unit according to an exemplary embodiment of the present disclosure.

FIG. 17A illustrates a schematic view of an example of a wearable device according to an exemplary embodiment of the present disclosure. FIG. 17B illustrates a schematic view of an example of a wearable device including an image capturing apparatus, according to an exemplary embodiment of the present disclosure.

FIG. 18A illustrates a schematic view of an example of an image forming apparatus according to an exemplary embodiment of the present disclosure. FIG. 18B illustrates a schematic view of an example of an exposure light source included in an image forming apparatus according to an exemplary embodiment of the present disclosure. FIG. 18C illustrates a schematic view of an example of an exposure light source included in an image forming apparatus according to an exemplary embodiment of the present disclosure.

### DETAILED DESCRIPTION

The present disclosure relates to an organic light emitting element including a light emitting region on a substrate. The light emitting region includes at least one electrode, an organic compound layer that covers the electrode, and a metallic layer. Further, the organic light emitting element includes a discrimination part consisting of at least one of a convex part and a concave part on at least one of an outer edge of the organic compound layer and an outer edge of the metallic layer. In the present exemplary embodiment, a convex part and a concave part of the discrimination part are convex and concave in a direction parallel to a surface of the substrate.

Further, in the present disclosure, a plurality of organic light emitting elements is simultaneously created by using a single substrate. In other words, light emitting regions of a plurality of organic light emitting elements are formed on a single substrate, and each of the organic light emitting elements is acquired by cutting the substrate into each of the light emitting regions. Uncut organic light emitting elements in a continuous state may be referred to as a chip. Discrimination parts of organic light emitting elements within the chip are different from each other. Therefore, a position of an uncut chip can be identified by the discrimination part even after the chip is cut.

Hereinafter, exemplary embodiments are described with reference to the appended drawings. Although a plurality of features is described in the below-described exemplary embodiments, not all of the features are essentially required for the present disclosure, and the plurality of features may be combined optionally. Further, in the appended drawings, the same reference numerals are applied to constituent elements identical or similar to each other, and duplicative descriptions thereof are omitted.

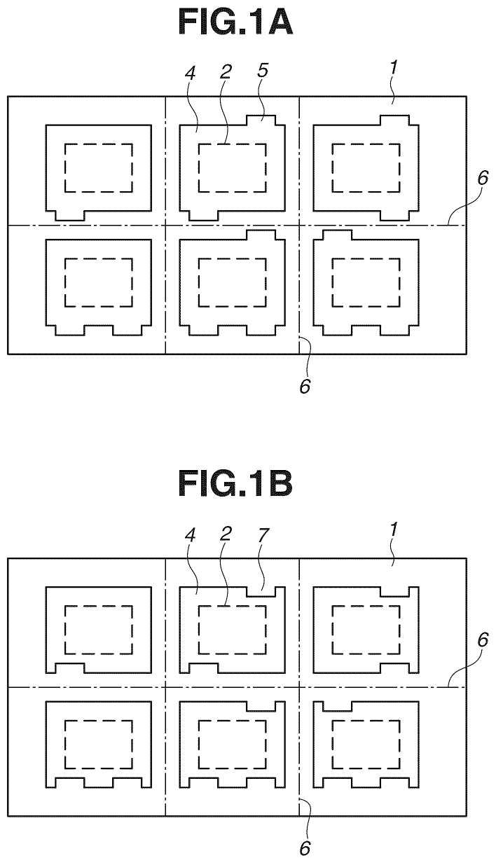

FIG. 1A illustrates an exemplary embodiment of discrimination parts consisting of convex parts. FIG. 1B illustrates an exemplary embodiment of discrimination parts consisting of concave parts. Structures of uncut chips of organic light emitting elements according to an exemplary embodiment of the present disclosure are schematically illustrated in FIGS. 1A and 1B. In both of the exemplary embodiments illustrated in FIGS. 1A and 1B, an organic compound layer and a metallic layer (collectively organic compound layer/metallic layer) 4 are formed to cover each of light emitting regions 2 on a substrate 1, and a convex part 5 as a discrimination part is formed on the organic compound layer/metallic layer 4 in FIG. 1A, and a concave part 7 as a discrimination part is formed on the organic compound layer/metallic layer 4 in FIG. 1B. The convex part 5 and the concave part 7 are not so limited, as long as the convex part 5 and the concave part 7 can be discriminated by any of presence/absence, the number of pieces, a position, a size, a shape, and a color.

Although sizes of the convex part 5 and the concave part 7 are not limited, a width and a height of the convex part 5 and a depth of the concave part 7 may be 10 μm to 1000 μm, and may be greater than or equal to 50 μm with consideration for visibility and processing accuracy of the convex part 5 and the concave part 7 in a vapor deposition mask.

The convex part 5 and an opening of the concave part 7 may be formed into a trapezoidal shape, a triangular shape, a polygonal shape, or a rectangular shape with rounded corners, depending on a film formation conditions such as a positional relationship between a substrate, a vapor deposition mask, and a vapor deposition source, a degree of vacuum during film formation, a film formation speed, and a rotation speed of a substrate, or on processing accuracy of the vapor deposition mask. However, the convex part 5 and the opening of the concave part 7 can be formed into any shape as long as the convex part 5 and the concave part 7 can be discriminated sufficiently. Therefore, a shape of the convex part 5 and an opening shape of the concave part 7 are not limited to a rectangular shape.

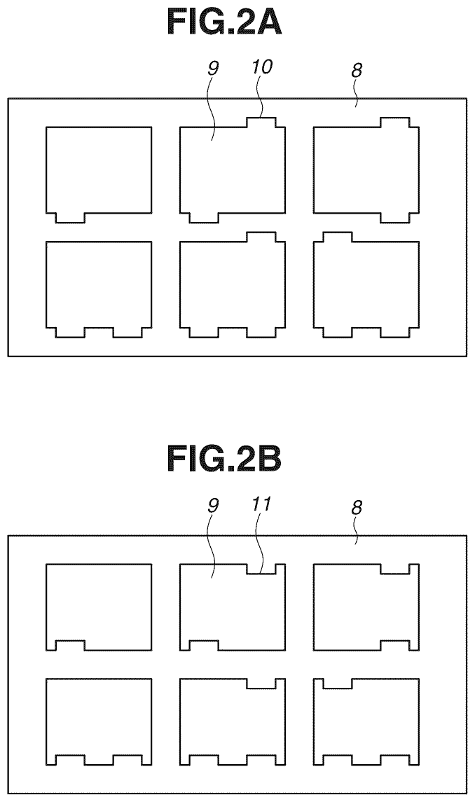

In FIGS. 1A and 1B, the discrimination part is formed on at least one layer of the organic compound layer/metallic layer 4 of a chip when vapor deposition is executed. FIGS. 2A and 2B illustrate schematic plan views of vapor deposition masks used for forming a layer having a discrimination part. FIG. 2A illustrates a mask used for forming a layer having the discrimination parts in FIG. 1A, and FIG. 2B illustrates a mask used for forming a layer having the discrimination parts in FIG. 1B.

As illustrated in FIGS. 2A and 2B, each of the vapor deposition masks 8 has openings 9 corresponding to shapes of the organic compound layer/metallic layer 4 having discrimination parts. Convex parts 10 corresponding to the convex parts 5 in FIG. 1A are formed on the openings 9 of the vapor deposition mask 8 in FIG. 2A, and concave parts 11 corresponding to the concave parts 7 in FIG. 1B are formed on the openings 9 of the vapor deposition mask 8 in FIG. 2B.

A metallic plate on which through-holes are formed by etching is known as the vapor deposition mask 8. Although the vapor deposition mask 8 can be made of any one of or a combination of materials such as stainless-steel, iron, copper, aluminum, silver, titanium, molybdenum, tungsten, invar, silicon, and resin, materials are not particularly limited to these materials. Further, a manufacturing method using plating is also known as a manufacturing method other than the manufacturing method using etching. However, the manufacturing method of the present disclosure of the vapor deposition mask 8 is not so limited.

At least one layer of the organic compound layer/metallic layer 4 is formed by the vacuum deposition method. A method may be employed using a point source as a vapor deposition source, which forms a film while rotating a substrate, which is a film formation target, or a method may be employed using a linear source as a vapor deposition source, which forms a film while relatively moving a crucible and a substrate.

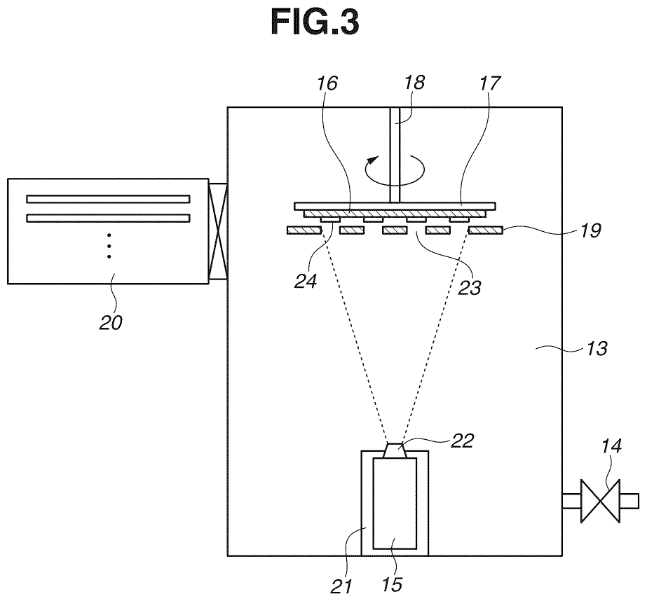

FIG. 3 is a schematic view of a configuration of a vapor deposition apparatus in which a substrate is rotated, which includes a point source as a vapor deposition source.

FIG. 3 illustrates a schematic cross-sectional view in a vertical direction. A film forming chamber 13 where vapor deposition is executed is connected to an exhaust pipe 14 for exhausting and evacuating the air through an exhaust pump such as a cryopump or a dry pump.

A vapor deposition source 15 which stores organic materials and metallic materials used for film formation and a substrate 16 as a film formation target are arranged inside the film forming chamber 13, and a vapor deposition mask 19 is arranged between the vapor deposition source 15 and the substrate 16.

A desired vapor deposition mask 19 is selected and conveyed to the film forming chamber 13 from another chamber, a mask stock chamber 20, connected to the film forming chamber 13 while maintaining a vacuum, and the vapor deposition mask 19 is placed in a vicinity of the substrate 16. Normally, a plurality of vapor deposition masks 19 are prepared and used depending on a pattern to be formed and materials to be used.

The vapor deposition source 15 is heated by a heater 21 arranged in the vicinity, and vapor deposition materials are radially ejected from a nozzle 22 arranged on the vapor deposition source 15. The ejected materials pass through openings 23 formed on the vapor deposition mask 19 to reach the substrate 16, and form vapor deposited layers 24.

The substrate 16 is held by a substrate holder 17, and film formation is executed through vapor deposition while the substrate 16 is rotated by a substrate rotation shaft 18.

The openings 23 of the vapor deposition mask 19 are formed into opening shapes having the convex parts 10 in FIG. 2A and/or the concave parts 11 in FIG. 2B, so that desired convex parts and/or concave parts are formed on outer edges of the vapor deposited layers 24 on the substrate 16.

Further, although the vapor deposition apparatus in FIG. 3 has one vapor deposition source and one film forming chamber, a plurality of vapor deposition sources may be arranged in the film forming chamber, so that vapor deposition can be executed by using one or a plurality of vapor deposition sources. In a case where the organic compound layer is a multi-layer film, a plurality of film forming chambers may be arranged. In this way, multi-layer films can be formed by using a different film forming chamber for each layer.

In the present disclosure, presence/absence, the number of pieces, positions, sizes, shapes, and colors of the convex parts and the concave parts formed on the organic compound layer and the metallic layer are changed for each of organic light emitting elements within a single substrate. In this way, a position of an organic light emitting element may be identified in an uncut chip.

Unlike the method discussed in Japanese Patent Application Laid-Open No. 2011-171128, which requires the processing for forming discrimination information on each of organic light emitting elements by using a laser marker or the like, a method according to the present disclosure forms discrimination information on organic light emitting elements through vacuum vapor deposition using a vapor deposition mask that can be executed simultaneously with formation of a film by vapor deposition. Further, the method according to the present disclosure can be collectively executed on all of organic light emitting elements within the substrate. Also, even when the number of organic light emitting elements cut out from a single substrate is to be increased, this can be managed by changing specifications of the openings formed on the vapor deposition mask. Therefore, discrimination information can be formed without increasing the number of processes for forming a film, and without preparing the additional apparatus.

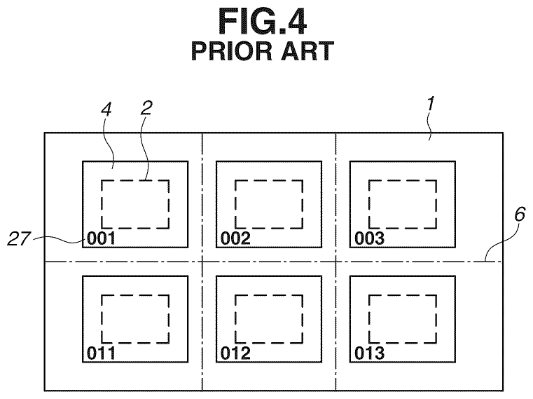

FIG. 4 is a schematic plan view of a chip in which a discrimination number is applied to the organic compound layer/metallic layer for each of the organic light emitting elements through a conventional method. In I FIG. 4, a numeral is applied as a discrimination number 27. In a case where the above-described discrimination number 27 is to be reduced in size, it is difficult to process a numeral and a letter on a vapor deposition mask for forming the discrimination number 27, and it is also difficult to discriminate the numeral and the letter. In the present exemplary embodiment, simple shapes such as a convex part and a concave part are used as discrimination information. Therefore, processing can be executed in comparison to the processing for forming a numeral or a letter. Further, even if the convex part and the concave part are reduced in size, discrimination of these parts is easier than discrimination of a letter or a numeral.

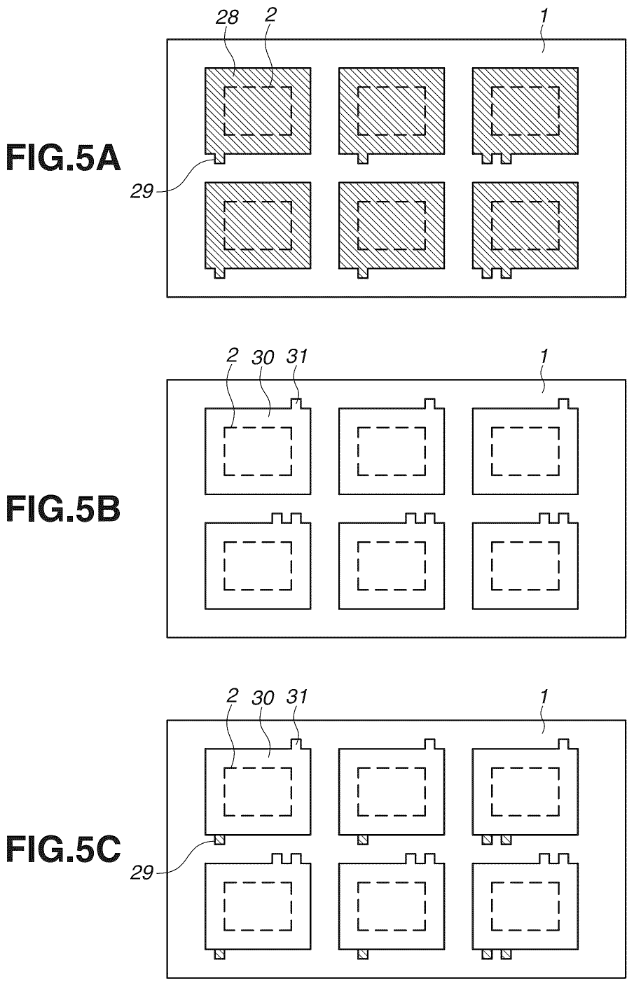

FIGS. 5A to 5C illustrate schematic plan views of uncut chips of organic light emitting elements according to another exemplary embodiment of the present disclosure. In the present exemplary embodiment, convex parts are formed on both of the organic compound layer and the metallic layer.

FIG. 5A illustrates a planar shape of an organic compound layer, FIG. 5B illustrates a planar shape of a metallic layer, and FIG. 5C illustrates a planar shape when vapor deposition is performed up to the metallic layer. FIG. 5A is a schematic plan view of the organic compound layer 28 on the substrate 1. Convex parts 29 are formed on the outer edges of the organic compound layer 28. Three patterns of convex parts 29 are formed depending on positions where the convex parts 29 are formed and the number of the convex parts 29. FIG. 5B is a schematic plan view of the metallic layer 30. Convex parts 31 are formed on the outer edges of the metallic layer 30. Two patterns of convex parts 31 are formed depending on positions where the convex parts 31 are formed and the number of the convex parts 31. FIG. 5C illustrates a schematic plan view when the metallic layer 30 in FIG. 5B is laminated on top of the organic compound layer 28 in FIG. 5A. As illustrated in FIG. 5C, a convex part 29 is formed on the organic compound layer 28 at a position on the lower side of the light emitting region 2, and a convex part 31 is formed on the metallic layer 30 at a position on the upper side of the light emitting region 2. Then, depending on a combination of a pattern of the convex part 29 of the organic compound layer 28 and a pattern of the convex part 31 of the metallic layer 30, six patterns of convex parts can be acquired as discrimination parts. Because the organic compound layer 28 and the metallic layer 30 have different colors, the convex part 29 and the convex part 31 can visually be distinguished.

In FIGS. 5A to 5C, a convex part 29 of the organic compound layer 28 and a convex part 31 of the metallic layer 30 are formed in different places. However, in a case where a translucent metallic layer 30 having optical transmissivity is laminated on top of the organic compound layer 28, a color of a formed film becomes different from the colors of the organic compound layer 28 and the metallic layer 30. Therefore, discrimination parts can be discriminated even if a discrimination part of the organic compound layer 28 and a discrimination part of the metallic layer 30 are formed in a same place in an overlapping manner.

The organic compound layer 28 normally consists of a plurality of layers made of different materials, laminated one on top of the other, and the convex parts 29 can be formed on all or only a part of the layers. A discrimination part illustrated in FIG. 5C may be formed by forming different patterns of the convex parts 29 on two or more layers made of different film materials selected from the organic compound layer 28, without forming the convex part 31 on the metallic layer 30.

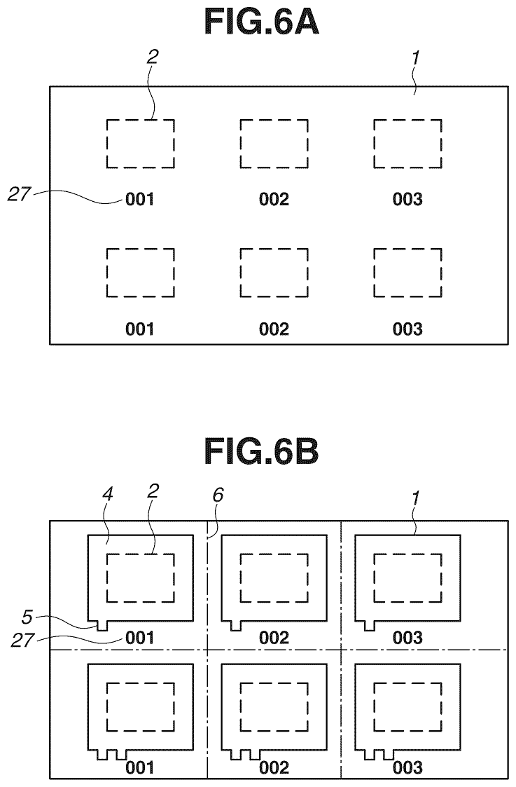

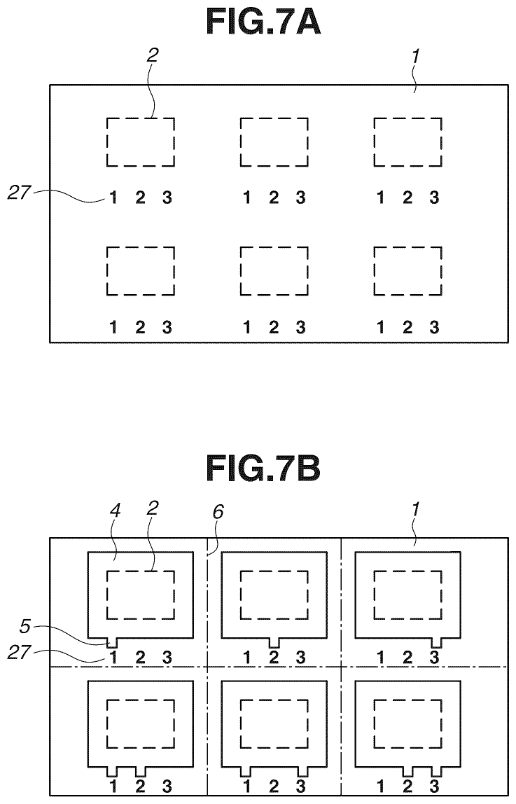

FIGS. 6A and 6B and FIGS. 7A and 7B illustrate schematic plan views of uncut chips of the organic light emitting elements according to other exemplary embodiments of the present disclosure. As illustrated in each of FIGS. 6A, 6B, 7A and 7B, a discrimination number 27 is previously applied to the substrate 1, and the organic compound layer/metallic layer 4 having a convex part 5 is formed on the substrate 1. Each of FIGS. 6A and 7A illustrates a state before the organic compound layer/metallic layer 4 is formed, and each of FIGS. 6B and 7B illustrates a state after the organic compound layer/metallic layer 4 is formed.

FIG. 6A illustrates a state where discrimination numbers are applied, and FIG. 6B illustrates a state where the organic compound layer and/or the metallic layer are deposited. In the example illustrated in FIGS. 6A and 6B, three types of discrimination numbers 27 are previously applied to the substrate 1. Then, two types of convex parts 5, i.e., one convex part 5 and two convex parts 5, are formed on the organic compound layer/metallic layer 4 in combination with the discrimination numbers 27, so that six types of discrimination parts are formed. An engraving method using a laser marker is generally used for applying a discrimination number 27 to the substrate 1. An upper limit value is set to the number of discrimination numbers 27 depending on the number of elements to be manufactured from a single substrate and specifications of the apparatus. In a case where discrimination numbers greater than the upper limit value are formed, discrimination numbers are formed repeatedly. Therefore, a plurality of same discrimination numbers is formed. In this case, chips having the identical discrimination numbers are not distinguishable when organic light emitting elements are cut and separated from the substrate. In order to increase the number of formable discrimination numbers, a laser marker is additionally introduced for engraving a discrimination number and/or a peripheral apparatus, and specifications may also be changed.

FIG. 7A illustrates a state where discrimination numbers are applied, and FIG. 7B illustrates a state where the organic compound layer and/or the metallic layer are deposited. In the example illustrated in FIGS. 7A and 7B, three types of discrimination numbers 27 are previously applied to the substrate 1. Then, one or two convex parts 5 are formed in a different place of the organic compound layer/metallic layer 4, so that six types of discrimination parts are acquired. As illustrated in the example in FIG. 7B, each of discrimination numbers “1”, “2”, and “3” applied to the substrate 1 is used as information indicating a position of the convex part 5. Therefore, positional accuracy for discriminating a convex part 5 is improved, and an effect of preventing false recognition of a discrimination part can be acquired.

In any of the examples illustrated in FIGS. 6A to 7B, a convex part 5 formed on the organic compound layer/metallic layer 4 can be combined with a discrimination number 27 formed on the substrate 1 without interference. Further, a concave part may be formed on the organic compound layer/metallic layer 4 and combined with a discrimination number 27.

An opening of the vapor deposition mask for forming a film formation region of the organic compound layer/metallic layer 4 may be wider than the light emitting region 2 within the substrate. Further, a place where a convex part 5 or a concave part is formed on the outer edge of the opening may be selected so that an element characteristic is not affected thereby.

An organic light emitting element includes at least one electrode (an anode or a cathode) in a light emitting region on a substrate, and an organic compound layer and a metallic layer are formed to cover the electrode. Then, electric power supplied from a wiring substrate connected to the electrode causes the organic compound layer to emit light, so that light is extracted from the organic light emitting element. The metallic layer may be used as a counter electrode (a cathode or an anode) opposite to the above-described electrode.

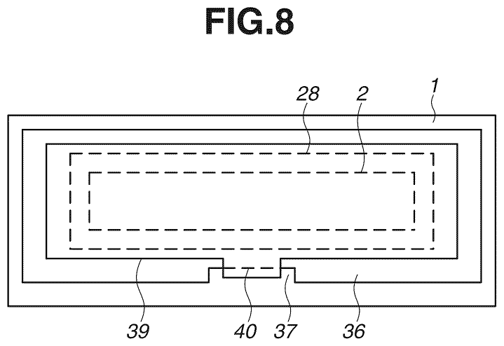

FIG. 8 illustrates a schematic plan view of a configuration example of a general organic light emitting element. As illustrated in FIG. 8, an anode electrode 36, an organic compound layer 28 as a light emitting body, and a cathode electrode 39 as a metallic layer are laminated in that order from a side of the substrate 1. The organic compound layer 28 is placed between the anode electrode 36 and the cathode electrode 39. An insulation layer may be arranged on the outer edge of the organic compound layer 28, so that the anode electrode 36 and the cathode electrode 39 are electrically insulated thereby. The electric power is respectively supplied to the anode electrode 36 and the cathode electrode 39 from a wiring substrate arranged on the outside of the organic light emitting element.

It is often the case that the organic light emitting element includes a contact region which makes the electrode readily connectable to the wiring substrate arranged outside the organic light emitting element. An example of a cathode contact as a contact region of the cathode electrode is described with reference to FIG. 8.

To supply electric power from the wiring substrate arranged on the outside, the cathode electrode 39 is to be led in to the concave part 37. In the configuration example illustrated in FIG. 8, the concave part 37 is formed on a part of the outer edge of the anode electrode 36, and the convex part 40 of the cathode electrode 39 provided as a discrimination part and arranged on the concave part 37, also serves as a lead-in part of the cathode electrode 39. In the configuration example in FIG. 8, only one cathode contact region is arranged on the outer edge of the anode electrode 36. However, depending on a shape and/or performance of the chip, a plurality of cathode contact regions may be arranged, or the cathode contact region may be widened, in order to sufficiently supply electric power to the organic light emitting element, or to make electric currents uniformly flow into a plane of the organic compound layer serving as a light emitting layer. The convex part and the concave part formed on the organic compound layer and the metallic layer according to the present are located on the outer edge of the film formation region. Therefore, the region be set so as may not to degrade a function of the cathode contact.

In a case where the cathode contact region is designed as illustrated in the configuration example in FIG. 8, the convex part can be arranged by making use of the cathode contact region without newly designing a place for arranging the convex part. Therefore, a discrimination part can be applied to each of organic light emitting elements by changing a mask used for film formation of the organic compound layer and the metallic layer. In this way, when analysis is conducted, the existing organic light emitting elements may be tracked, which may not otherwise be discriminated after the chips are cut.

In the above-described exemplary embodiment, a convex part and a concave part formed on the organic compound layer and the metallic layer are arranged on one side or two sides of the light emitting region. However, the number of sides and places where the convex part and the concave part are arranged are not limited to the above-described exemplary embodiment.

When vapor deposition is executed in a state where a vapor deposition mask is in close proximity to the substrate, there is a case where the vapor deposition mask is supported by making a protrusion (i.e., a rib) arranged on a part of a frame of the vapor deposition mask contact the substrate. A film cannot be formed in a region where the vapor deposition mask contacts the substrate. Therefore, the rib may be arranged in a region by avoiding a region where the convex part or the concave part is formed.

### Configuration of Organic Light Emitting Element

Hereinafter, additional configurations of the organic light emitting element according to the present disclosure are described. Normally, an organic light emitting element is arranged by forming an insulation layer, a first electrode (the anode electrode 36 in FIG. 8), an organic compound layer (the organic compound layer 28 in FIG. 8), and a second electrode (the cathode electrode 39 in FIG. 8) on a substrate (the substrate 1 in FIG. 8). The organic compound layer includes at least a light emitting layer. A protection layer, a color filter, and a microlens may be arranged on the second electrode. In a case where a color filter is to be arranged, a planarization layer may be arranged between the protection layer and the color filter. The planarization layer can be made of acrylic resin. The same also applies for the case where a planarization layer is to be arranged between the color filter and the microlens.

Hereinafter, configurations of the organic light emitting element according to the present disclosure and an apparatus including the organic light emitting element are described.

### Substrate

A quartz substrate, a glass substrate, a silicon wafer, a resin substrate, and a metallic substrate are given as example of the substrate. Further, the substrate may include wiring and a switching element such as a transistor, and an insulation layer may be arranged on top of the switching element and the wiring. A material used for the insulation layer is not limited, as long as a contact hole for connecting the wiring to the first electrode can be formed on the insulation layer while the insulation layer can ensure insulation from wiring which should not be connected to. For example, resin such as polyimide, oxide silicon, or silicon nitride can be used as a material of the insulation layer.

### Electrode

The organic light emitting element includes a pair of electrodes. In a case where an electric field is applied in a direction in which the organic light emitting element emits light, an electrode having higher potential is an anode electrode, and the other electrode is a cathode electrode. In other words, an electrode which supplies holes to the light emitting layer is the anode electrode, and an electrode which supplies electrons is the cathode electrode. In the present disclosure, any one of the anode electrode and the cathode electrode can be specified as a first electrode, on a substrate side.

A material whose work function is as large as possible may be used as a constituent material of the anode electrode. For example, single metals such as gold, platinum, silver, copper, nickel, palladium, cobalt, selenium, vanadium, and tungsten, a compound containing these metals, an alloy made by combining these metals, and metal oxides such as a tin oxide, an indium oxide, an indium tin oxide (ITO), an indium zinc oxide (IZO), and a zinc oxide (ZnO) can be used. Further, conductive polymers such as polyaniline, poly-pyrrole, and poly-thiophene can also be used.

These electrode materials may be used independently, or may be used in combination of two or more types. The anode electrode may also consist of a single layer or a plurality of layers.

In a case where the anode electrode is used as a reflective electrode, a metallic material such as chrome, aluminum, silver, titanium, tungsten, or molybdenum, an alloy made by combining these metallic materials, or a material made by laminating these metallic materials can be used. By using the above-described materials, the anode electrode can function as a reflective film which does not function as an electrode. In a case where the anode electrode is used as a transparent electrode, a transparent conductive layer made of oxide materials such as an indium tin oxide (ITO), an indium zinc oxide (IZO), and a zinc oxide (ZnO) can be used, but the materials are not limited thereto. A photolithographic technique can be used for formation of the electrode.

On the other hand, a material with a small work function may be used as a constituent material of the cathode electrode. For example, an alkali metal such as lithium, an alkaline-earth metal such as calcium, single metals such as aluminum, titanium, manganese, silver, lead, and chromium, and a compound containing these metals can be used. Alternatively, an alloy made by combining these single metals can also be used. For example, an alloy of magnesium and silver, an alloy of aluminum and lithium, an alloy of aluminum and magnesium, an alloy of silver and copper, and an alloy of zinc and silver can be used. A metal oxide such as an indium tin oxide (ITO) can also be used. These electrode materials may be used independently, or may be used in combination of two or more types. The cathode electrode may consist of a single layer or a plurality of layers. Silver may be used as a constituent material of the cathode electrode. In this case, a silver alloy may be used to reduce aggregation of silver. A silver alloy of any ratio may be used as long as aggregation of silver can be reduced. For example, a ratio of silver to the other metal may be 1:1 or 3:1.

Although a top emission-type element may be formed by using a cathode electrode consisting of a conductive layer made of an oxide material such as ITO, or a bottom emission-type element may be formed by using a reflective electrode made of aluminum (Al), the present exemplary embodiment is not so limited. Although a method for forming a cathode electrode is not so limited, a sputtering method using direct current or alternating current may be used because a film can be formed with favorable coverage, and resistance can be lowered.

Specifically, in the present exemplary embodiment, a thin film whose thickness is controlled to make the film translucent may be used as the anode electrode 36 in FIG. 6, and metal oxides having electrical conductivity, such as an indium tin oxide (ITO), an indium zinc oxide (IZO), and a zinc oxide (ZnO), and metals (including an alloy) such as silver, platinum, and aluminum can may be used for the thin film. An alkali metal such as lithium, an alkaline-earth metal such as calcium, metals (including an alloy) such as silver and aluminum can may be used for the cathode electrode 39 in FIG. 6. A film thickness of the electrode is not limited by presence or absence of the convex part or the concave part of the organic compound layer and the metallic layer, and the electrode may have a film thickness with which the element can sufficiently exert its function.

### Organic Compound Layer

Although the organic compound layer includes a hole transport layer, a light emitting layer, and an electron transport layer, for example, a multi-layer film consisting of a plurality of function layers or a single layer film can also be laminated. The plurality of function layers includes a hole injection layer and an electron injection layer for facilitating supplying of holes and electrons to the light emitting layer, a hole blocking layer and an electron blocking layer for blocking excessive movement of holes and electrons, and a buffer layer for adjusting the movement of holes and electrons from the electrode.

In a case where the organic light emitting element according to the present disclosure includes a plurality of electrodes on the substrate, the organic compound layer is formed on top of the plurality of electrodes as a common layer. The common layer is a layer arranged to extend across a plurality of organic light emitting elements.

The organic compound layer can be formed by employing a dry process, such as a vacuum deposition method, an ionized deposition method, a sputtering method, or a plasma method. A wet process can also be used instead of the dry process. In the wet process, a layer is formed by applying organic materials dissolved in a solvent through a known application method (e.g., a spin coating method, a dipping method, a casting method, a Langmuir-Blodgett (LB) method, or an ink jet method).

By forming the organic compound layer through the vacuum vapor deposition method or the solution application method, occurrence of crystallization can be reduced, and the organic compound layer can be excellent in temporal stability. In a case where a film is formed by an application method, a film can be formed by applying a solution in combination with appropriate binder resin.

Although various types of resin, such as polyvinyl carbazole resin, polycarbonate resin, polyester resin, acrylonitrile-butadiene-styrene (ABS) resin, acrylic resin, polyimide resin, phenolic resin, epoxy resin, silicone resin, and urea resin can be given as examples of the above-described binder resin, binder resin is not limited thereto.

The above-described various types of binder resin may independently be used as a homopolymer or a copolymer, or may be used in combination of two or more types. As necessary, a known additive agent, such as a plasticizing agent, an antioxidizing agent, or an ultraviolet absorbing agent may be used in combination.

### Protection Layer

A protection layer may be arranged on top of the second electrode. For example, a glass on which a moisture absorbent is arranged is adhered on top of the second electrode. In this way, entry of moisture into the organic compound layer can be reduced, and occurrence of display failure can be reduced. As another exemplary embodiment, entrance of moisture into the organic compound layer may be reduced by arranging a passivation film such as a silicon nitride film on top of the second electrode. For example, after the second electrode is formed on the substrate, the substrate is conveyed to another chamber while maintaining a vacuum, and a silicon nitride film having a thickness of 2 um may be formed as a protection layer by a chemical vapor deposition (CVD) method. A protection layer formed by an atomic layer deposition (ALD) method may be arranged after the silicon nitride film is formed by the CVD method. A material of the film formed by the ALD method is not limited, and can be a silicon nitride, a silicon oxide, or an aluminum oxide. A silicon nitride film formed by the CVD method may further be arranged on the film formed by the ALD method. A thickness of the film formed by the ALD method can be thinner than a thickness of the film formed by the CVD method. A thickness of the film formed by the ALD method may be 50% or less than a thickness of the film formed by the CVD method, or may be 10% or less.

### Color Filter

A color filter may be arranged on top of the protection layer. For example, a color filter may be arranged on another substrate in consideration of a size of the organic light emitting element, and this substrate may be bonded to the substrate on which the organic light emitting element is arranged. Alternatively, a color filter may be patterned onto the above-described protection layer through a photolithographic technique. In addition, the color filter may be a high-molecular color filter.

### Planarization Layer

A planarization layer may be arranged between the color filter and the protection layer. The planarization layer is arranged for the purpose of reducing irregularity of a layer on the lower side. The planarization layer may also be a resinous material layer, without limitation thereto. The planarization layer may be made of an organic compound, and may be a low-molecular layer or a high-molecular layer.

The planarization layer may be arranged on both of the upper side and the lower side of the color film, and constituent materials of these planarization layers can be the same or different. Specifically, polyvinyl carbazole resin, polycarbonate resin, polyester resin, ABS resin, acrylic resin, polyimide resin, phenolic resin, epoxy resin, silicone resin, and urea resin can be given as examples of the constituent material.

### Microlens

An organic light emitting element or an organic light emitting apparatus including the organic light emitting element may have an optical member such as a microlens on a light emitting side thereof. The microlens can be made of a material such as acrylic resin or epoxy resin. The microlens may be provided for the purpose of controlling an increase of amount of light extracted from the organic light emitting element or the organic light emitting apparatus, and for the purpose of controlling a direction of light to be extracted. The microlens may have a semispherical shape. In a case where the microlens has a semispherical shape, a contact point where a tangential line parallel to an insulation layer is in contact with a spherical-shape microlens, from among tangential lines in contact with the semispherical-shape microlens, is an apex of the microlens. The apex of the microlens can similarly be determined in an optional cross-sectional view. In other words, a contact point where a tangential line parallel to an insulation layer is in contact with a semicircular-shape microlens, from among tangential lines in contact with the semicircular-shape microlens in the cross-sectional view, is an apex of the microlens.

A midpoint of the microlens may be defined. In a cross-sectional face of the microlens, a midpoint of an imaginary line segment from one end point of an arc shape to another end point of the ark shape can be called a midpoint of the microlens. The cross-sectional face for determining the apex and the midpoint may be a cross-sectional face vertical to the insulation layer.

### Counter Substrate

A counter substrate may be arranged on top of the planarization layer. A substrate arranged at a position facing the above-described substrate is called a counter substrate. A constituent material same as the constituent material of the above-described substrate (i.e., a substrate on a side of the first electrode) can be used for the counter substrate. The counter substrate may also be called a second substrate when the above-described substrate is called a first substrate.

### Pixel Circuit

The organic light emitting apparatus including the organic light emitting element may also include a pixel circuit connected to the organic light emitting element. The pixel circuit may be an active matrix-type pixel circuit which independently controls light emission of a plurality of light emitting elements. The active matrix-type circuit can be implemented by a voltage programming or a current programming. A driving circuit includes a pixel circuit for each pixel. The pixel circuit may include a light emitting element, a transistor for controlling light emission luminance of the light emitting element, a transistor for controlling a light emission timing, a capacity for retaining a gate voltage of the transistor for controlling the light emission luminance, and a transistor for connecting to a ground (GND) without the light emitting element.

The light emitting apparatus includes a display region and a peripheral region arranged in the periphery of the display region. A pixel circuit is arranged in the display region, and a display control circuit is arranged in the peripheral region. Mobility of a transistor for constituting the pixel circuit can be lower than mobility of a transistor for constituting the display control circuit. Inclination of current-voltage characteristics of a transistor for constituting the pixel circuit can be smaller than inclination of current-voltage characteristics of a transistor for constituting the display control circuit. The inclination of the current-voltage characteristics can be measured by a Vg-Ig characteristic. The transistor for constituting the pixel circuit is a transistor connected to a light emitting element such as the first light emitting element.

### Pixel

The organic light emitting apparatus including the organic light emitting element may include a plurality of pixels. Each of the pixels includes sub-pixels mutually emitting light of different colors. For example, sub-pixels may respectively emit light of red (R), green (G), and blue (B) colors.

A region also called a pixel opening of the pixel emits light. The pixel opening may be 15 μm or less and 5 μm or more. More specifically, the pixel opening may be 11 μm, 9.5 μm, 7.4 μm, or 6.4 μm. A space between sub-pixels may be 10 μm or less, more specifically, the space may be 8 μm, 7.4 μm, or 6.4 μm.

The pixels may be arranged in a plan view. For example, the pixels may be arranged in a stripe arrangement, a delta arrangement, a pen-tile arrangement, or a Bayer arrangement. The sub-pixel may have any one of a known shape in a plan view. For example, a shape of the sub-pixel may be a quadrangular shape, such as a rectangular shape or a diamond shape, a hexagonal shape, and the like. Naturally, a shape does not have to be an accurate figure, and a shape similar to a rectangular shape can be regarded as the rectangular shape. A shape of the sub-pixel and a pixel arrangement can be used in combination.

### Usage of Organic Light Emitting Element

The organic light emitting element according to the present disclosure can be used as a constituent member of a display apparatus and an illumination apparatus.

The organic light emitting element can also be used for an exposure light source of an electrophotographic image forming apparatus, a backlight of a liquid crystal display apparatus, a light emitting apparatus including a white light source with a color filter, and the like.

The display apparatus may be an image information processing apparatus for displaying an input image on a display unit, the display apparatus including an image input unit for receiving image information from an area charge-coupled device (CCD) sensor, a linear CCD sensor, a memory card, and the like, and an information processing unit for processing the received information. The display apparatus includes a plurality of pixels. At least one of the plurality of pixels includes the organic light emitting element according to the present exemplary embodiment and a transistor connected to that organic light emitting element.

A display unit included in an image capturing apparatus or an ink jet printer may have a touch panel function. A driving method of the touch panel function is not limited, and can be an infrared method, a capacitance method, a resistive film method, or an electromagnetic induction method. The display apparatus may be used as a display unit mounted on a multifunction printer.

Next, a display apparatus according to the present exemplary embodiment is described with reference to the appended drawings.

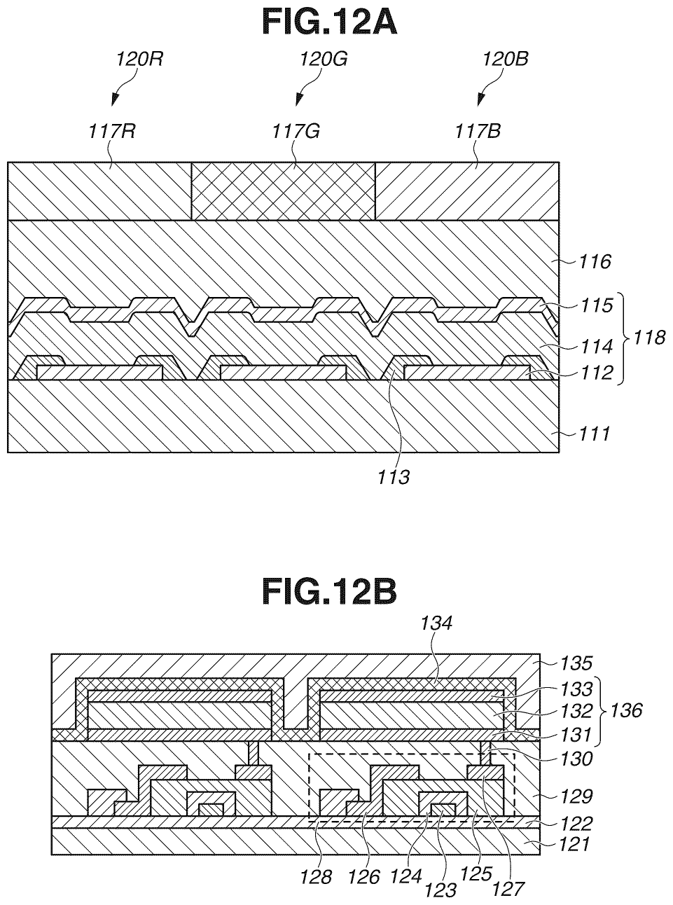

FIGS. 12A and 12B illustrate cross-sectional schematic views of an example of the organic light emitting element according to the present exemplary embodiment and an example of the display apparatus which includes a transistor connected to this organic light emitting element.

FIG. 12A illustrates an example of a pixel, which is a constituent element of the display apparatus according to the present exemplary embodiment. The pixel includes sub-pixels 120. The sub-pixels 120 are also called sub-pixels 120R, 120G, and 120B depending on the emitted light. An emission color may be discriminated by a wavelength of light emitted from a light emission layer. Light emitted from each of the sub-pixels 120 may be selectively transmitted by a color filter or the emission color may be converted by the color filter. Each of the sub-pixels 120 includes a first electrode 112 serving as a reflective electrode, an insulation layer 113 that covers an edge of the first electrode 112, an organic compound layer 114 that covers the first electrode 112 and the insulation layer 113, a second electrode 115, a protection layer 116, and a color filter 117, which are arranged on an interlayer insulation layer 111. The first electrode 112, the organic compound layer 114, and the second electrode 115 constitute the organic light emitting element 118 according to the present exemplary embodiment.

A transistor and a capacitance element may be arranged on a layer on the lower side of the interlayer insulation layer 111, or on an inner part of the interlayer insulation layer 111. The transistor and the first electrode 112 may electrically be connected to each other via a contact hole or the like.

The insulation layer 113, also called bank or pixel separation film, is arranged in a circumference of the first electrode 112 to cover the edge of the first electrode 112. A portion of the first electrode 112, where the insulation layer 113 is not arranged, is in contact with the organic compound layer 114 and serves as a light emitting region.

The protection layer 116 reduces the moisture permeating into the organic compound layer 114. Although the protection layer 116 in FIG. 12A is illustrated as a single layer, the protection layer 116 may consist of a plurality of layers. Then, each of the layers may be an inorganic compound layer or an organic compound layer.

Color filters 117 are also called color filters 117R, 117G, and 117B depending on the colors.

The color filters 117 may be formed on a planarization film. A resin protection layer may be arranged on top of the color filters 117. The color filters 117 may be formed on the protection layer 116. Alternatively, the color filters 117 may be provided on a counter substrate such as a glass substrate and then bonded to the organic light emitting element 118.

The display apparatus in FIG. 12B includes an organic light emitting element 136 and a thin-film transistor (TFT) 128 as one example of a transistor. An insulation layer 122 is arranged on the upper side of a substrate 121 made of a material such as glass or silicon, and the TFT 128 including a gate electrode 123, a gate insulation film 124, a semiconductor layer 125, a drain electrode 126 and a source electrode 127 is arranged on the insulation layer 122. An insulation film 129 is arranged on the TFT 128, and the source electrode 127 is connected to a positive pole 131 included in the organic light emitting element 136 via a contact hole 130 provided in the insulation film 129.

A method for electrically connecting the electrodes (i.e., a positive pole 131 and a negative pole 133) included in the organic light emitting element 136 to the electrodes (i.e., a source electrode 127 and a drain electrode 126) included in the TFT 128 is not limited to the method illustrated in FIG. 12B. Any method can be used as long as any one of the positive pole 131 and the negative pole 133 and any one of the source electrode 127 and the drain electrode 126 are electrically connected to each other.

A first protection layer 134 and a second protection layer 135 for reducing degradation of the organic light emitting element are arranged on top of the negative pole 133.

Light emission luminance of the organic light emitting element 136 according to the present exemplary embodiment is controlled by the TFT 128. Then, the organic light emitting elements 136 are arranged in a plurality of planes, so that an image can be displayed at respective light emitting luminance levels.

The display apparatus in FIG. 12B uses a transistor as a switching element. However, another switching element can be used instead of the transistor.

A transistor used for the display apparatus in FIG. 12B is not limited to a TFT having an active layer on a surface of the insulation layer on the substrate, and a transistor using a single crystal silicon wafer can also be used. The active layer may be non-single crystal silicon such as amorphous silicon or microcrystal silicon, or a non-single crystal oxide semiconductor such as an indium zinc oxide or an indium gallium zinc oxide.

The transistor may be formed of low-temperature polysilicon or an active-matrix driver formed on a substrate such as a silicon substrate, and “on a substrate” may be rephrased as “within a substrate”. As to whether to arrange a transistor or a TFT within a substrate is selected depending on a size of a display unit. For example, an organic light emitting element may be arranged on a silicon substrate if a size of the display unit is approximately 0.5 inches. Herein, a transistor formed within a substrate means that a transistor is created by processing a substrate (such as a silicon substrate) itself. Thus, a transistor included within a substrate may be interpreted as a transistor formed integrally with a substrate.

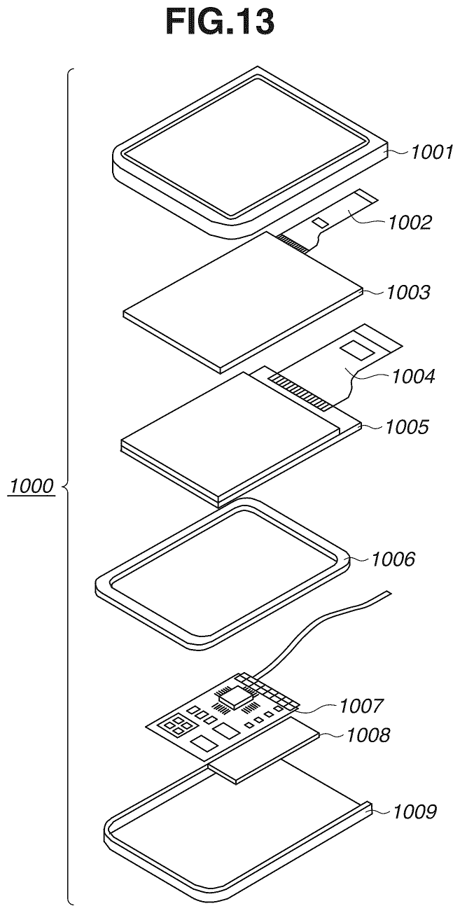

FIG. 13 illustrates a schematic view of an example of a display apparatus according to the present exemplary embodiment. A display apparatus 1000 includes a touch panel 1003, a display panel 1005, a frame 1006, a circuit substrate 1007, and a battery 1008 arranged between a top cover 1001 and a bottom cover 1009. Flexible print circuits FPC 1002 and 1004 are respectively connected to the touch panel 1003 and the display panel 1005. A transistor is printed on the circuit substrate 1007. The battery 1008 does not have to be provided on the display apparatus 1000 if the display apparatus 1000 is not a mobile device, or if the display apparatus 1000 is a mobile device, the battery 1008 may be arranged at another position.

The display apparatus 1000 according to the present exemplary embodiment may include color filters of red, green, and blue. The color filters of respective colors of red, green and blue may be arranged in a delta array.

The display apparatus 1000 according to the present exemplary embodiment is used for a display unit of a mobile terminal. In this case, the display apparatus 1000 may have both of a display function and an operation function. A mobile phone such as a smartphone, a tablet terminal, and a head-mounted display can be given as examples of the mobile terminal.

The display apparatus 1000 according to the present exemplary embodiment is used for a display unit of an image capturing apparatus which includes an optical unit having a plurality of lenses and an image sensor for receiving light having passed through the optical unit. The image capturing apparatus may have a display unit for displaying information acquired by the image sensor. The display unit may be exposed to the outside of the image capturing apparatus, or may be arranged inside a finder. The image capturing apparatus can be a digital camera or a digital video camera.

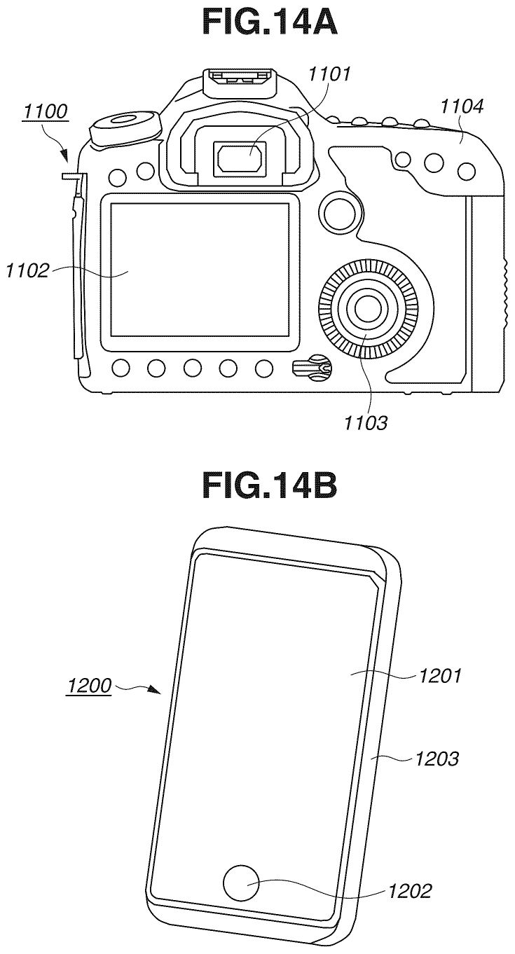

FIG. 14A illustrates a schematic view of an example of an image capturing apparatus according to the present exemplary embodiment. An image capturing apparatus 1100 includes a viewfinder 1101, a back-face display 1102, an operation unit 1103, and a housing 1104. The viewfinder 1101 includes the display apparatus according to the present exemplary embodiment. In this case, the display apparatus may display environmental information and image capturing instructions in addition to an image to be captured. Information about intensities and a direction of outside light, information about moving speed of an object, and information about a possibility that an object would be covered by a shielding object may be displayed as the environmental information.

Because a timing suitable for capturing images lasts for only a moment, it is better to display the above-described information as soon as possible. Accordingly, the display apparatus may use an organic light emitting element according to the present disclosure. This is because the organic light emitting element can quickly respond. The display apparatus using an organic light emitting element may be used for the above-described apparatuses and liquid crystal display apparatuses which require display speed.

The image capturing apparatus 1100 may include an optical unit. The optical unit includes a plurality of lenses, and forms an image on an image sensor housed inside the housing 1104. The plurality of lenses can adjust a focus by adjusting relative lens positions. This operation can also be executed automatically. The image capturing apparatus 1100 may also be called a photoelectric conversion apparatus. The photoelectric conversion apparatus can execute image capturing methods such as a method for detecting a difference from a previous image and a method for cutting out an image from images constantly being recorded, instead of executing a method for sequentially capturing images.

FIG. 14B illustrates a schematic view of an example of an electric device according to the present exemplary embodiment. An electronic device 1200 includes a display unit 1201, an operation unit 1202, and a housing 1203. The housing 1203 may include a circuit, a print substrate having the circuit, a battery, and a communication unit. The operation unit 1202 may be a button or a touch panel-type reaction unit. The operation unit 1202 may be a biometric recognition unit which releases a lock by recognizing a fingerprint. The electronic device including the communication unit can also be called a communication device. A lens and an image sensor may be mounted on the electronic device, so that the electronic device can also execute a camera function. An image captured by the camera function is displayed on the display unit. A smartphone and a notebook-size personal computer can be given as examples of the electronic device.

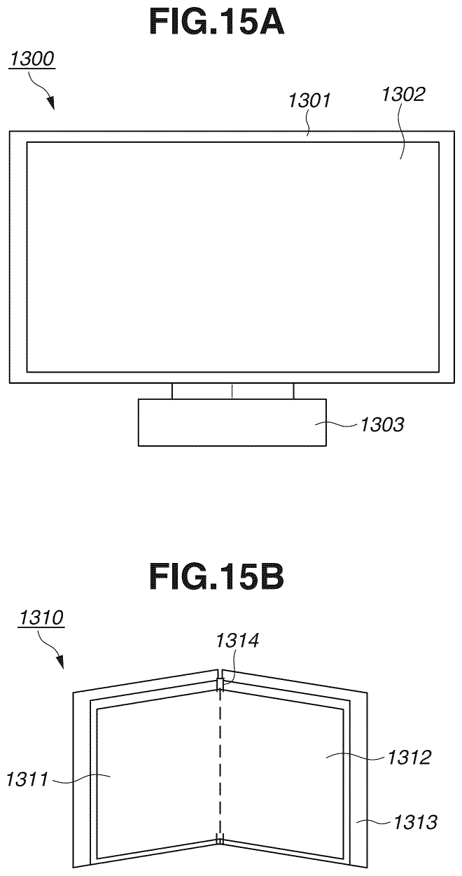

FIGS. 15A and 15B illustrate schematic views of examples of the display apparatus according to the present exemplary embodiment. FIG. 15A illustrates a display apparatus such as a TV monitor or a PC monitor. A display apparatus 1300 includes a frame 1301 and a display unit 1302. The light emitting apparatus according to the present exemplary embodiment is used for the display unit 1302. The display apparatus 1300 further includes a base 1303 for supporting the frame 1301 and the display unit 1302. The base 1303 is not limited to the embodiment illustrated in FIG. 15A. A lower side of the frame 1301 may serve as a base. Further, each of the frame 1301 and the display unit 1302 may have a curved shape. A curvature radius of the curved shape may be 5000 mm or more and 6000 mm or less.

FIG. 15B illustrates a schematic view of another example of the display apparatus according to the present exemplary embodiment. A display apparatus 1310 in FIG. 15B is a so-called foldable display apparatus capable of being folded. The display apparatus 1310 includes a first display unit 1311, a second display unit 1312, a housing 1313, and a folding point 1314. Each of the first display unit 1311 and the second display unit 1312 includes the light emitting apparatus according to the present exemplary embodiment. The first display unit 1311 and the second display unit 1312 may be a single display apparatus without a seam. The first display unit 1311 and the second display unit 1312 can be divided at the folding point 1314. Each of the first display unit 1311 and the second display unit 1312 may display a different image, or may display a single image together.

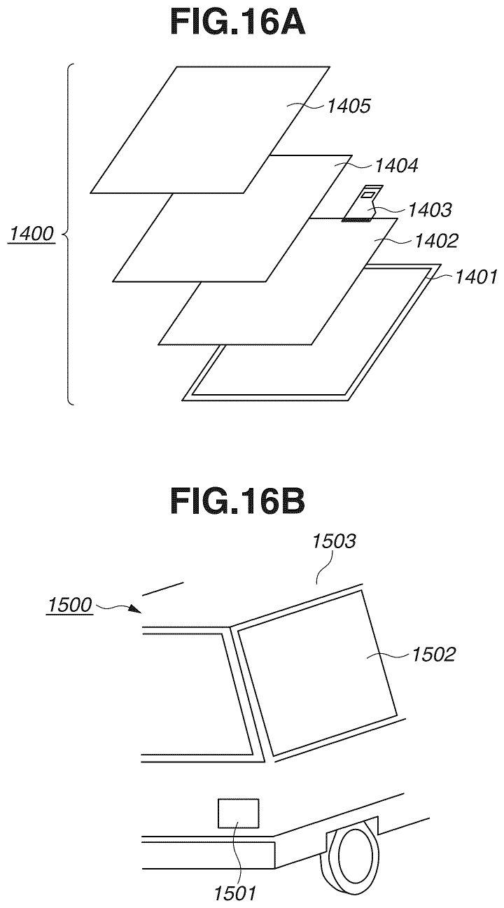

FIG. 16A illustrates a schematic view of an example of an illumination apparatus according to the present exemplary embodiment. An illumination apparatus 1400 includes a housing 1401, a light source 1402, a circuit substrate 1403, an optical filter 1404, and a light diffusion unit 1405. The light source 1402 includes the organic light emitting elements according to the present exemplary embodiment. The optical filter 1404 may be a filter that improves a color rendering property of the light source 1402. The light diffusion unit 1405 can deliver light to a wide area to light up the area by effectively diffusing light from the light source 1402. The optical filter 1404 and the light diffusion unit 1405 may be arranged on a side where illumination light is output. Further, a cover may be arranged on an outermost part of the illumination apparatus 1400 if necessary.

For example, the illumination apparatus 1400 is an apparatus for illuminating a room. The illumination apparatus 1400 may emit light of any color, such as white, daylight white, blue, and red. The illumination apparatus 1400 may include a light adjustment circuit for adjusting the light. The illumination apparatus 1400 includes the organic light emitting element according to the present exemplary embodiment and a power circuit connected thereto. The power circuit is a circuit for converting alternating current into direct current. White light is light having a color temperature of 4200 K, and daylight is light having a color temperature of 5000 K. The illumination apparatus 1400 may include a color filter.

The illumination apparatus 1400 according to the present exemplary embodiment may include a heat dissipation unit that dissipates heat within an apparatus to the outside. Materials such as a metal of high specific heat and a liquid silicon can be used for the heat dissipation unit.

FIG. 16B illustrates a schematic view of an automobile as one example of a moving body according to the present exemplary embodiment. The automobile includes a tail lamp as one example of a lamp unit. An automobile 1500 can include a tail lamp 1501 which turns on when a brake is operated.

The tail lamp 1501 includes the organic light emitting element according to the present exemplary embodiments. The tail lamp 1501 may include a protection member for protecting the organic light emitting element. Although any transparent materials having a certain degree of strength can be used for the protection member, the protection member may be made of a material such as polycarbonate. A derivative of furandicarboxylic acid or an acrylonitrile derivative may be mixed with the polycarbonate.

The automobile 1500 includes a car body 1503 and a window 1502 mounted on the car body 1503. The window 1502 can be a transparent display unless the window 1502 is used to check a front side and a rear side of the automobile 1500. This transparent display may include the organic light emitting element according to the present exemplary embodiment. In this case, a constituent member such as an electrode included in the organic light emitting element is made of a transparent material.

The moving body according to the present exemplary embodiment may be an ocean vessel, an aircraft, a drone, and the like. The moving body includes a body and a lamp unit mounted on the body. The lamp unit emits light in order to show a location of the body. The lamp unit includes the organic light emitting element according to the present exemplary embodiment.

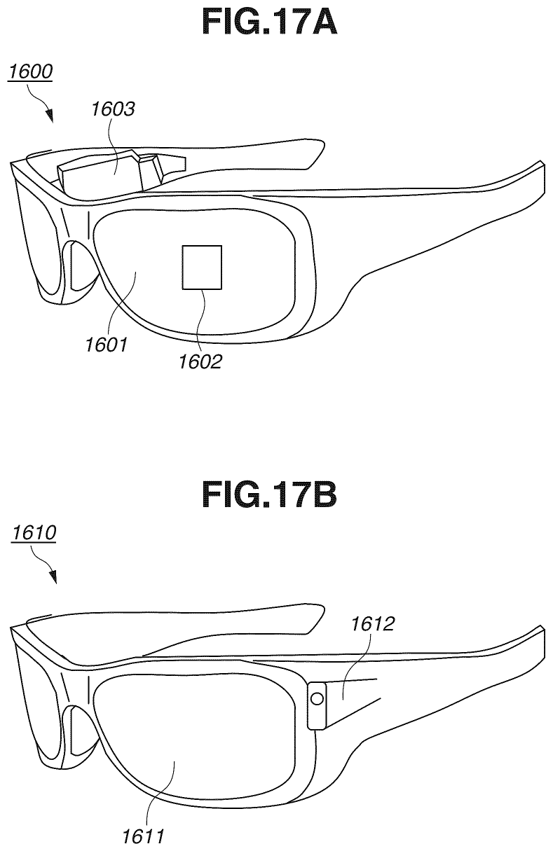

An application example of the display apparatus according to the above-described exemplary embodiments is described with reference to FIGS. 17A and 17B. The display apparatus can be applied to a system wearable as a wearable device, such as smart glasses, a head-mounted display (HMD), and smart contact lenses. The image capturing display apparatus used for the above-described application example includes an image capturing apparatus capable of photoelectrically converting visible light into electric signals and a display apparatus capable of emitting visible light.

FIG. 17A illustrates glasses (smart glasses) 1600 according to an application example. An image capturing apparatus 1602 such as a complementary metal-oxide semiconductor (CMOS) sensor or a single-photon avalanche diode (SAPD) is provided on each of the front faces of lenses 1601 mounted on the glasses 1600. The display apparatus according to the above-described exemplary embodiment is arranged on each of the back faces of the lenses 1601.

The glasses 1600 may also include a control apparatus 1603. The control apparatus 1603 functions as a power source for supplying power to the image capturing apparatus 1602 and the display apparatus according to the above-described exemplary embodiments. The control apparatus 1603 controls operations of the image capturing apparatus 1602 and the display apparatus. An optical system for condensing light to the image capturing apparatus 1602 is formed on each of the lenses 1601.

FIG. 17B illustrates glasses (smart glasses) 1610 according to an application example. The glasses 1610 include a control apparatus 1612. An image capturing apparatus corresponding to the image capturing apparatus 1602 in FIG. 17A and a display apparatus are mounted on the control apparatus 1612. The image capturing apparatus within the control apparatus 1612 and an optical system for projecting light emitted from the display apparatus are formed on each of lenses 1611, so that an image is projected on each of the lenses 1611. The control apparatus 1612 functions as a power source for supplying power to the image capturing apparatus and the display apparatus, and also controls operations of the image capturing apparatus and the display apparatus. The control apparatus 1612 may also include a line-of-sight detection unit for detecting a line-of-sight of the user wearing the glasses 1610. Infrared light may be used for detecting the line-of-sight. An infrared light emitting unit emits infrared light to the eyeballs of the user who is gazing at a displayed image. An image capturing unit including a light receiving element detects the emitted infrared light reflected on the eyeball, so that a captured image of the eyeball can be acquired. By arranging a reduction unit for reducing light emitted from the infrared light emitting unit to a display portion in a plan view, degradation of image quality can be reduced.

The user's line-of-sight directed to the display image is detected from the captured image of the eyeball acquired by the infrared light image capturing. An arbitrary known method can be used for the line-of-sight detection using the captured image of the eyeball. For example, method may be used for detecting a line-of-sight based on a Purkinje image acquired from irradiation light reflected on the cornea. More specifically, line-of-sight detection processing based on a pupil-corneal reflection method is executed. In the pupil-corneal reflection method, a line-of-sight vector which expresses the orientation (rotation angle) of the eyeball is calculated based on a pupil image and a Purkinje image included in the captured image of the eyeball, and a user's line-of-sight is detected from the calculated line-of-sight vector.

The display apparatus according to the present exemplary embodiment includes an image capturing apparatus including a light emitting element, and controls a display image displayed on the display apparatus based on the user's line-of-sight information received from the image capturing apparatus. Based on the line-of-sight information, the display apparatus determines a first field-of-view region where the user is gazing at, and a second field-of-view region different from the first field-of-view region. The first field-of-view region and the second field-of-view region may be determined by a control apparatus included in the display apparatus, or the display apparatus may receive the information about the first field-of-view region and the second field-of-view region determined by an external control apparatus. In the display region of the display apparatus, a display resolution may be controlled so that a display resolution in the first field-of-view region becomes higher than a display resolution in the second field-of-view region. In other words, a resolution of the second field-of-view region may be lower than a resolution of the first field-of-view region.

Further, the display region has a first display region and a second display region different from the first display region. Then, based on the line-of-sight information, a region having a higher priority is determined from the first and the second display regions. The first field-of-view region and the second field-of-view region may be determined by a control apparatus included in the display apparatus, or the display apparatus may receive the information about the first field-of-view region and the second field-of-view region determined by an external control apparatus. A resolution of the region having a higher priority may be controlled to be higher than a resolution of the region other than the region having the higher priority. In other words, a resolution of the region having a relatively low priority may be lowered.

In addition, an artificial intelligence (AI) program may be used for determining the first field-of-view region and a high-priority region. The AI program may be a model which estimates a line-of-sight angle and a distance to the object to which the line-of-sight is directed from an image of the eyeball based on teaching data which describes the image of the eyeball and the actual gazing direction of the eyeball captured in the image. The AI program may be included in the display apparatus, the image capturing apparatus, or an external apparatus. In a case where the AI program is included in the external apparatus, a result of estimation is transmitted to the display apparatus through communication.

In a case where display control is executed based on visual recognition detection, the present exemplary embodiment may be applied to smart glasses further including an image capturing apparatus for capturing an image of the outside. The smart glasses can display information about the captured outside image in real time.

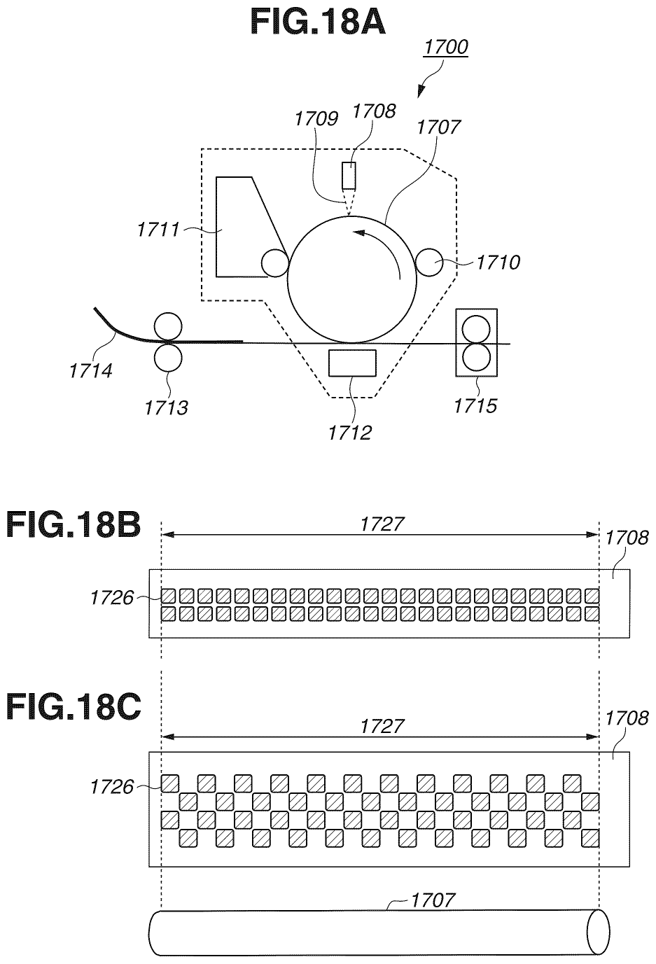

FIG. 18A illustrates a schematic view of an example of an image forming apparatus according to an exemplary embodiment of the present disclosure.

An image forming apparatus 1700 is an electrophotographic image forming apparatus including a photosensitive body 1707, an exposure light source 1708, a charging unit 1710, a development unit 1711, a transfer unit 1712, a conveyance roller pair 1713, and a fixing unit 1715. Light 1709 is emitted from the exposure light source 1708, so that an electrostatic latent image is formed on a surface of the photosensitive body 1707. This exposure light source 1708 includes the organic light emitting element according to the present exemplary embodiment. The development unit 1711 includes toner. The charging unit 1710 electrically charges the photosensitive body 1707. The transfer unit 1712 transfers a developed image to a recording medium 1714. The conveyance roller pair 1713 conveys the recording medium 1714. For example, the recording medium 1714 is a sheet of paper. The fixing unit 1715 fixes an image formed on the recording medium 1714.

FIGS. 18B and 18C illustrate the exposure light source 1708 and a plurality of light emitting units 1726 arranged on a long substrate. An arrow 1727 indicates a column direction in which organic light emitting elements are arranged. The column direction is parallel to an axis of the photosensitive body 1707. The column direction is a direction same as a rotation axis direction of the photosensitive body 1707. This direction can also be called a long axis direction of the photosensitive body 1707. In FIG. 18B, the light emitting units 1726 are arranged in a direction parallel to the long axis direction of the photosensitive body 1707. Each of the light emitting units 1726 includes the organic light emitting element according to the present exemplary embodiment.

An embodiment in FIG. 18C is different from the embodiment in FIG. 18B. In FIG. 18C, the light emitting units 1726 are alternately arranged in the first and the second columns in the column direction. The first column and the second column are arranged at different positions in a raw direction. In the first column, a plurality of light emitting units 1726 is arranged at intervals. In the second column, the light emitting units 1726 are arranged at positions corresponding to the intervals between the light emitting units 1726 arranged in the first column. In other words, a plurality of light emitting units 1726 are also arranged in the raw direction at intervals. The arrangement illustrated in FIG. 18C can be described as a grid-like arrangement, a houndstooth check-like arrangement, or a checkered-pattern arrangement.

As described above, by using an apparatus including the organic light emitting element according to the present exemplary embodiment, an image may be stably displayed for an extended time with improved image quality.

Examples are described below. However, the present disclosure is not limited to the below-described examples. Unless otherwise described in particular, terms the same as the terms used in the exemplary embodiments are also used in the examples, and duplicative descriptions are omitted.

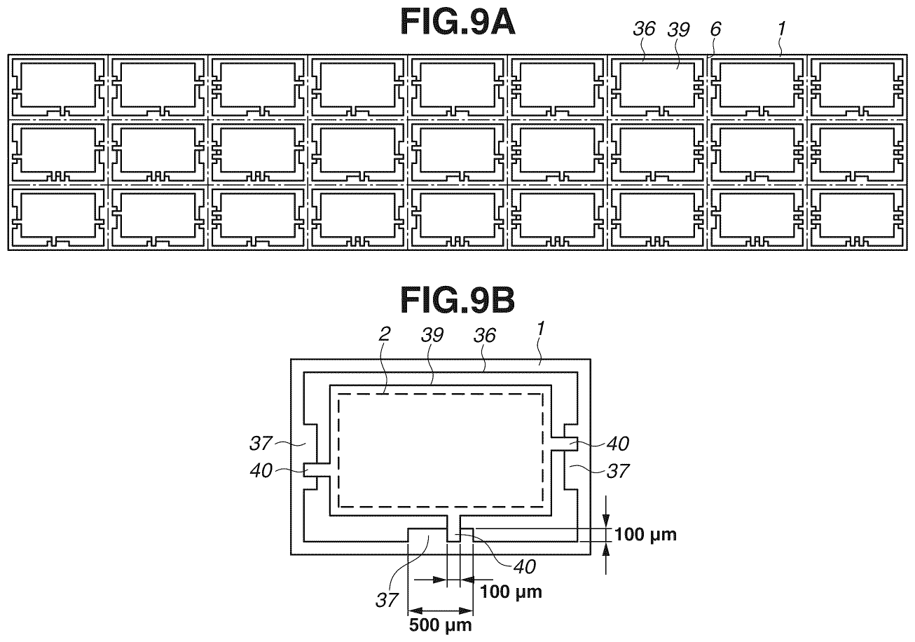

In Example 1, chips of twenty seven organic light emitting elements were created by using the vapor deposition apparatus illustrated in FIG. 3. FIGS. 9A and 9B illustrate schematic plan views. FIG. 9A illustrates an uncut chip, and FIG. 9B illustrates one organic light emitting element after the chip is cut. FIG. 9A illustrates an overall view of the organic light emitting elements, and FIG. 9B is an enlarged view of an organic light emitting element located on an upper left portion of the sheet surface in FIG. 9A.

In Example 1, an anode electrode 36 was formed to cover a light emitting region 2 on a substrate 1, an organic compound layer was formed on top of the anode electrode 36 in the light emitting region 2, and a cathode electrode (metallic layer) 39 was formed to cover the organic compound layer. Concave parts 37 to lead-in the cathode electrode 39 were arranged in three places in the anode electrode 36. The places where the concave parts 37 were arranged were the same for the twenty seven organic light emitting elements within the substrate 1. Convex parts 40 also serving as lead-in parts were formed in the cathode electrode 39, at positions on the concave parts 37 of the anode electrode 36, and a combination of the number and positions of the convex parts 40 was different for each of the twenty seven organic light emitting elements within the substrate 1.

On the sheet surface in FIG. 9A, one or two convex parts 40 were arranged on respective concave parts 37 located in three places on the left side, the right side, and the lower side of the anode electrode 36. With respect to the concave part 37 where only one convex part 40 was arranged, the one convex part 40 was arranged at any one of two positions, so that the number of combinations was 27 (3×3×3=27).

In the present example, the anode electrode 36 consisting of an aluminum (Al) film having a thickness of 50 nm was formed on the substrate 1 consisting of a silicon wafer having a thickness of 725 μm. A width and a depth of the concave part 37 of the anode electrode 36 were 500 μm and 100 μm, respectively. After the anode electrode 36 was formed, 120 nm of an organic compound layer 28 including a hole transport layer, a light emitting layer, and an electron transport layer was formed. Further, after the organic compound layer 28 was formed, a film made of an alloy of magnesium and silver, having a thickness of 20 nm, was formed as the cathode electrode 39. A convex part 40 of the cathode electrode 39 was formed so that a width of the convex part 40 was set to 100 μm, and a leading end portion of the convex part 40 was protruded to the concave part 37 by 100 μm.

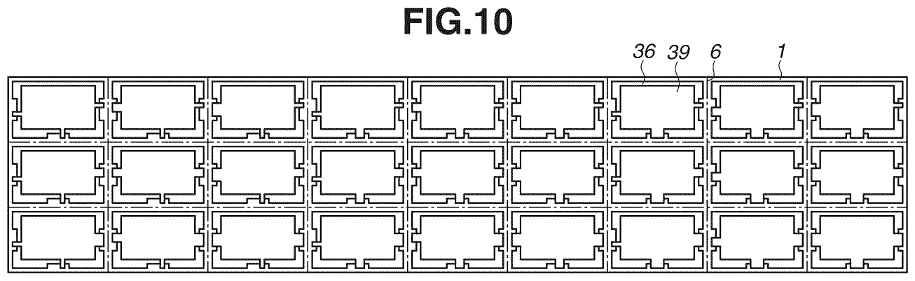

Example 2 is similar to Example 1, with chips of twenty seven organic light emitting elements created on the substrate 1 by using the vapor deposition apparatus illustrated in FIG. 3. FIG. 10 illustrates a schematic plan view. In Example 2, convex parts 40 having three different widths, 100 μm, 200 μm, and 300 μm were formed, so that the number of combinations was 27 (3×3×3=27).

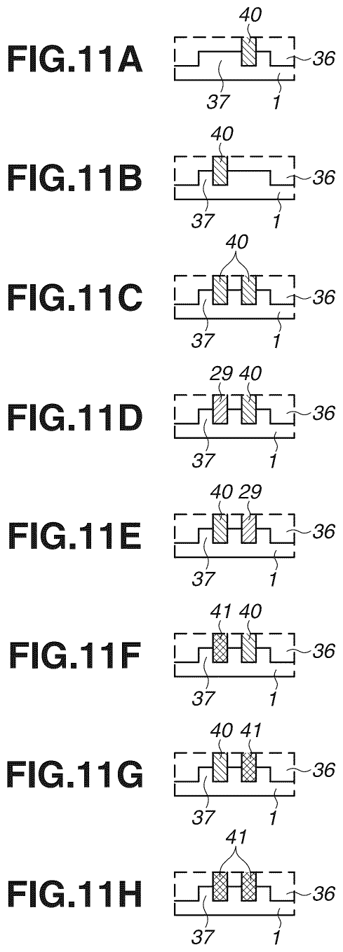

In Examples 1 and 2, a convex part was formed on a metallic layer and used as a discrimination part. In Example 3, convex parts were respectively formed on two layers of an organic compound layer and a metallic layer and used as a discrimination part in combination. Specifically, a nitrogen-containing heterocyclic derivative serving as an electron transport layer having a thickness of 10 nm was formed as an organic compound layer, and a cathode electrode having a thickness of 20 nm was laminated. Film formation of the organic compound layer and the cathode electrode was conducted by using the vapor deposition apparatus in FIG. 3 similarly used in Examples 1 and 2, and a vapor deposition mask was prepared for each of the organic compound layer and the metallic layer. The substrate 1, the light emitting region, the anode electrode 36, and a shape of the concave part 37 were similar to those described in Examples 1 and 2. A combination method is illustrated in FIGS. 11A to 11H.

As illustrated in FIGS. 11A to 11H, in Example 3, three types of convex parts, i.e., an independent convex part 29 of the organic compound layer, an independent convex part 40 of the cathode electrode, and a laminated convex part 41 of the convex parts 29 and 40, were formed in two places of the concave part 37 of the anode electrode. As a result, eight types of discrimination parts were acquired in total. Shapes of the convex parts 29 and 40 were substantially the same. Because the colors of the organic compound layer and the metallic layer were different, the convex parts 29 and 40 were discriminable even when the sizes were the same. Further, because the metallic layer was a translucent film having a thickness of 20 nm, a color of the metallic layer was superimposed on a color of the organic compound layer located on the lower side, in a case where the metallic layer was laminated on top of the organic compound layer. Therefore, a color of the laminated portion was different and discriminable from any of the colors of the organic compound layer and the metallic layer. In addition, because the convex part 40 of the cathode electrode was also used as a lead-in part of the cathode electrode, at least one of the convex parts 40 and 40 was formed in any of the discrimination parts illustrated in FIGS. 11A to 11H.

By arranging the concave parts 37 of the anode electrode 36 in three places within the organic light emitting element, discrimination of five hundred and twelve organic light emitting elements was possible (8×8×8 =512). In other words, in comparison to the number of discriminable organic light emitting elements (i.e., 27) in Examples 1 and 2, the number of discriminable organic light emitting elements can be increased dramatically.

In the present disclosure, a concave part and a convex part used as discrimination parts are formed on outer edges of the organic compound layer and the metallic layer which constitute the organic light emitting element. In this way, discrimination information can be applied to each of the organic light emitting elements without increasing the manufacturing processing loads and/or special facilities. The above-described discrimination part can be reduced in size because discrimination of the discrimination part is easier than discrimination of a letter or a symbol. Thus, a greater number of organic light emitting elements may be acquired from a single substrate and organic light emitting elements having discrimination information may be acquired at lower cost.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims priority to and the benefit of Japanese Patent Application No. 2024-084717, filed May 24, 2024, the entirety of which is incorporated herein by reference.

What is claimed is:

1. An organic light emitting element comprising:
a light emitting region on a part of a substrate, the light emitting region including at least one electrode, an organic compound layer that covers the at least one electrode, and a metallic layer that covers the organic compound layer,
wherein a discrimination part including at least one of a convex part and a concave part is arranged on at least one of an outer edge of the organic compound layer and an outer edge of the metallic layer.

2. The organic light emitting element according to claim 1, wherein the discrimination part has two or more different forms that include one or more of a number of pieces, a position, a size, a shape, and a color of the at least one of the convex part and the concave part.

3. The organic light emitting element according to claim 1, wherein the organic light emitting element is formed on a single substrate and is separated from the substrate, and
wherein a position of the organic light emitting element on the substrate is identified by the discrimination part.

4. The organic light emitting element according to claim 1, wherein the metallic layer is at least one other electrode.

5. An organic light emitting element comprising:
a light emitting region on a part of a substrate, the light emitting region including at least one electrode, an organic compound layer that covers the at least one electrode, and a metallic layer that covers the organic compound layer,
wherein each discrimination part of a plurality of discrimination parts includes a respective at least one of a convex part and a concave part arranged on respective outer edges of at least two layers made of different film materials than the organic compound layer and the metallic layer.

6. A method for manufacturing the organic light emitting element according to claim 1, the method comprising:
forming, on the substrate, a plurality of light emitting regions, each including at least one electrode, an organic compound layer that covers the at least one electrode and a metallic layer that covers the organic compound layer;
separating each light emitting region of the plurality of light emitting regions by cutting the substrate; and
when at least one of the organic compound layer and the metallic layer is to be formed by vapor deposition, using a vapor deposition mask having openings whose shapes are different for at least each of the light emitting regions,
wherein each of the openings has at least one of a convex part and a concave part.

7. A method for manufacturing the organic light emitting element according to claim 5, the method comprising:
forming a plurality of light emitting regions, each including at least one electrode, an organic compound layer that covers the at least one electrode, and a metallic layer that covers the organic compound layer, on the substrate; and
cutting the substrate into each light emitting region of the plurality of light emitting regions; and
when at least two layers made of different film materials are respectively formed by vapor deposition from among the organic compound layer and the metallic layer, a vapor deposition mask having openings whose shapes are different for at least each of the light emitting regions is used, wherein each of the openings has at least one of a convex part and a concave part.

8. A display apparatus comprising a display unit including the organic light emitting element according to claim 1 and a housing on which the display unit is mounted.

9. A photoelectric conversion apparatus comprising:
an image sensor configured to receive light; and
a display unit configured to display an image captured by the image sensor,
wherein the display unit includes the organic light emitting element according to claim 1.

10. An electronic device comprising:
a display unit including the organic light emitting element according to claim 1;
a housing on which the display unit is mounted; and
a communication unit mounted on the housing, the communication unit being configured to perform external communication.

11. A wearable device comprising:
a display unit including the organic light emitting element according to claim 1;
an optical system configured to condense light of the display unit; and
a control apparatus configured to control output of the display unit.

12. An illumination apparatus comprising:
a light source including the organic light emitting element according to claim 1; and
a housing on which the light source is mounted.

13. A moving body comprising:
a lamp unit including the organic light emitting element according to claim 1; and
a body on which the lamp unit is mounted.

14. An image forming apparatus comprising:
a photosensitive body; and
an exposure light source configured to expose the photosensitive body to light, the exposure light source including the organic light emitting element according to claim 1.
